(19) United States
(12) Patent Application Publication
(10) Pub. No.: US 2024/0421207 A1
(43) Pub. Date: Dec. 19, 2024

(54) SEMICONDUCTOR DEVICE

(71) Applicant: Samsung Electronics Co., Ltd., Suwon-si (KR)

(72) Inventors: Jiho Yoo, Suwon-si (KR); Kihyung Ko, Suwon-si (KR); Jihoon Cha, Suwon-si (KR)

(21) Appl. No.: 18/670,738

(22) Filed: May 22, 2024

(30) Foreign Application Priority Data
Jun. 19, 2023 (KR) 10-2023-0077962

(51) Int. Cl. H01L 29/423; H01L 23/528; H01L 29/06; H01L 29/08; H01L 29/66; H01L 29/775; H01L 29/786

(52) U.S. Cl. CPC H01L 29/42392; H01L 23/5286; H01L 29/0649; H01L 29/0673; H01L 29/0847; H01L 29/66545; H01L 29/66553; H01L 29/775; H01L 29/78696

(57) ABSTRACT

A semiconductor device includes a substrate insulating layer having a lower insulating pattern protruding from an upper surface of the substrate insulating layer and extending in a first direction; a semiconductor pattern extending on the lower insulating pattern of the substrate insulating layer in the first direction; a plurality of channel layers stacked on the semiconductor pattern and spaced apart from each other in a direction perpendicular to the upper surface of the substrate insulating layer; a gate structure intersecting the semiconductor pattern, extending in a second direction crossing the first direction, and surrounding the plurality of channel layers; first and second source/drain regions disposed on the semiconductor pattern on both sides of the gate structure; and an intermediate insulating pattern disposed between the lower insulating pattern and the semiconductor pattern and having a thickness equal to or less than a distance between the plurality of channel layers.

### CROSS-REFERENCE TO RELATED APPLICATION(S)

This application claims priority under 35 U.S.C. 119 to Korean Patent Application No. 10-2023-0077962 filed on Jun. 19, 2023 in the Korean Intellectual Property Office, the disclosure of which is incorporated herein by reference in its entirety.

### BACKGROUND

The present inventive concept relates to a semiconductor device.

While demands for high performance, high speed, and/or multifunctionality of semiconductor devices have increased, the integration density of semiconductor devices has increased. As a semiconductor device tends to be highly integrated, a semiconductor device having a backside power delivery network (BSPDN) structure in which power rails are disposed on a rear surface of a wafer has been developed. Also, there have been efforts to develop a semiconductor device having a 3D structured channel to overcome limitations in operating characteristics due to size reductions of a planar metal oxide semiconductor FET (MOSFET).

### SUMMARY

An aspect of the present inventive concept provides a semiconductor device having improved electrical properties and reliability.

According to an aspect of the present inventive concept, a semiconductor device includes a substrate insulating layer having a lower insulating pattern protruding from an upper surface of the substrate insulating layer and extending in a first direction; a semiconductor pattern extending on the lower insulating pattern of the substrate insulating layer in the first direction; a plurality of channel layers stacked on the semiconductor pattern and spaced apart from each other in a direction perpendicular to the upper surface of the substrate insulating layer; a gate structure intersecting the semiconductor pattern, extending in a second direction crossing the first direction, and surrounding the plurality of channel layers; first and second source/drain regions disposed on the semiconductor pattern on both sides of the gate structure and electrically connected to the plurality of channel layers; an intermediate insulating pattern disposed between the lower insulating pattern and the semiconductor pattern and having a thickness equal to or less than a distance between the plurality of channel layers; a vertical insulating pattern penetrating the substrate insulating layer, the intermediate insulating pattern and the semiconductor pattern and in contact with a lower surface of the first source/drain region; a first contact structure connected to an upper surface of the first source/drain region; and a second contact structure penetrating through the substrate insulating layer, the intermediate insulating pattern and the semiconductor pattern and contacting a lower surface of the second source/drain region.

According to an aspect of the present inventive concept, a semiconductor device includes a substrate insulating layer; a semiconductor pattern extending on the substrate insulating layer in a first direction; a plurality of channel layers spaced apart from each other in a direction perpendicular to an upper surface of the substrate insulating layer on the substrate insulating layer; gate structures surrounding the plurality of channel layers on the substrate insulating layer and extending in a second direction perpendicular to the first direction; source/drain regions disposed on external sides of the gate structures; a vertical insulating pattern in contact with a bottom surface of the source/drain regions; and a backside contact structure spaced apart from the vertical insulating pattern in the first direction and electrically connected to at least one of the source/drain regions, wherein the vertical insulating pattern includes a body portion penetrating the substrate insulating layer and extending from a lower surface of the source/drain regions toward a lower surface of the substrate insulating layer, and a protrusion surrounding at least a portion of a side surface of the body portion.

According to an aspect of the present inventive concept, a semiconductor device includes a substrate insulating layer; a fin-type structure extending on the substrate insulating layer in a first direction and including a lower insulating pattern, an intermediate insulating pattern and a semiconductor pattern stacked in order; a channel structure disposed on the fin-type structure in a direction perpendicular to an upper surface of the substrate insulating layer; a gate structure intersecting the fin-type structure, surrounding the channel structure, and extending in a second direction orthogonal to the first direction; first and second source/drain regions disposed on external sides of the gate structure; a vertical insulating pattern penetrating through the fin-type structure and extending from a lower surface of the first source/drain region toward a lower surface of the substrate insulating layer; and a backside contact structure spaced apart from the vertical insulating pattern in the first direction and electrically connected to the second source/drain region.

### BRIEF DESCRIPTION OF DRAWINGS

The above and other aspects, features, and advantages in the example embodiment will be more clearly understood from the following detailed description, taken in combination with the accompanying drawings, in which:

FIG. 1 is a plan diagram/view illustrating a semiconductor device according to an example embodiment of the present disclosure;

FIG. 2A is a cross-sectional diagram/view illustrating a semiconductor device taken along line I-I′ in FIG. 1;

FIG. 2B are cross-sectional diagrams/views illustrating a semiconductor device taken along lines II1-II1′ and II2-II2′ in FIG. 1;

FIG. 3A is a cross-sectional diagram/view illustrating a semiconductor device taken along a line corresponding to line I-I′ of FIG. 1 according to an example embodiment of the present disclosure;

FIG. 3B is cross-sectional diagrams/views illustrating a semiconductor device taken along lines corresponding to lines II1-II1′ and II2-II2′ of FIG. 1 according to an example embodiment of the present disclosure;

FIG. 4A is a cross-sectional diagram/view illustrating a semiconductor device taken along a line corresponding to line I-I′ of FIG. 1 according to an example embodiment of the present disclosure;

FIG. 4B is cross-sectional diagrams/views illustrating a semiconductor device taken along lines corresponding to lines II1-II1′ and II2-II2′ of FIG. 1 according to an example embodiment of the present disclosure;

FIG. 5A is a cross-sectional diagram/view illustrating a semiconductor device taken along a line corresponding to line I-I′ of FIG. 1 according to an example embodiment of the present disclosure;

FIG. 5B is cross-sectional diagrams/views illustrating a semiconductor device taken along lines corresponding to lines II1-II1′ and II2-II2′ of FIG. 1 according to an example embodiment of the present disclosure;

FIG. 6A is a cross-sectional diagram/view illustrating a semiconductor device taken along a line corresponding to line I-I′ of FIG. 1 according to an example embodiment of the present disclosure;

FIG. 6B is cross-sectional diagrams/views illustrating a semiconductor device taken along lines corresponding to lines II1-II1′ and II2-II2′ of FIG. 1 according to an example embodiment of the present disclosure; and

FIGS. 7A to 18B are cross-sectional diagrams/views illustrating processes of a method of manufacturing a semiconductor device in order according to example embodiments of the present disclosure.

### DETAILED DESCRIPTION

Hereinafter, example embodiments will be described with reference to the accompanying drawings.

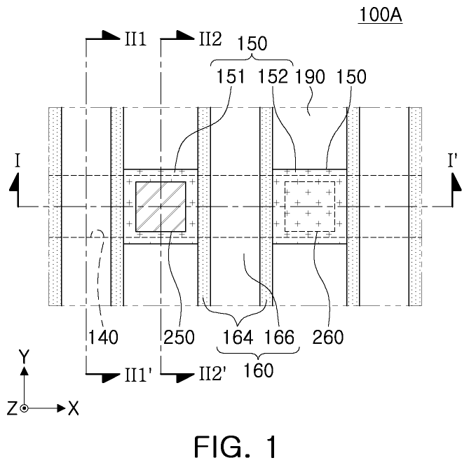

FIG. 1 is a plan diagram illustrating a semiconductor device 100A according to an example embodiment.

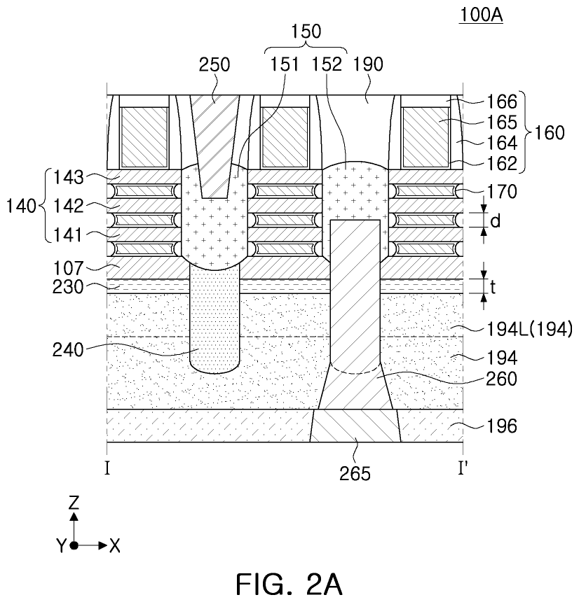

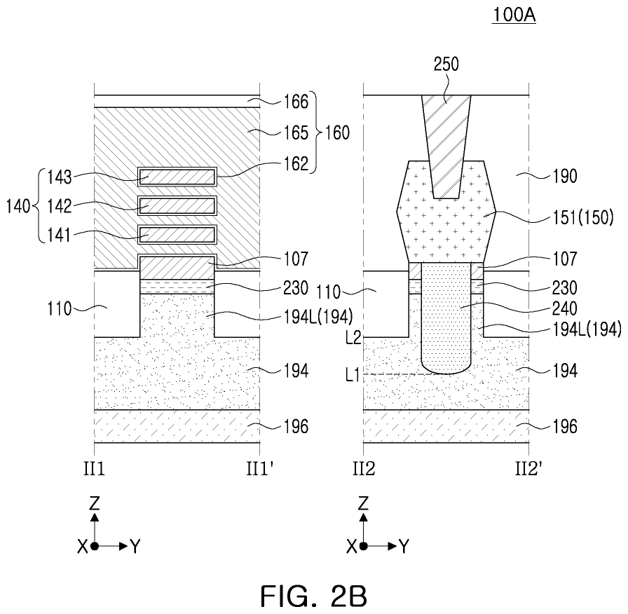

FIG. 2A is a cross-sectional diagram illustrating a semiconductor device taken along line I-I′ in FIG. 1. FIG. 2B are cross-sectional diagrams illustrating a semiconductor device taken along lines II1-II1′ and II2-II2′ in FIG. 1. For ease of description, only the main components of the semiconductor device are illustrated in FIGS. 1, 2A and 2B. For example, some other components included in the semiconductor device are not illustrated in FIGS. 1, 2A and 2B for ease of illustration.

Referring to FIGS. 1, 2A and 2B, a semiconductor device 100A according to the example embodiment may include a substrate insulating layer 194 having a lower insulating pattern 194L extending (e.g., lengthwise) in a first direction (e.g., X-direction), a semiconductor pattern 107 extending (e.g., lengthwise) in the first direction (e.g., X-direction) on the substrate insulating layer 194, a channel structure 140 including first to third channel layers 141, 142, and 143 stacked and spaced apart from each other in a direction (e.g., Z-direction) perpendicular to an upper surface of the substrate insulating layer 194 on the semiconductor pattern 107, a gate structure 160 intersecting the semiconductor pattern 107 and extending (e.g., lengthwise) in a second direction (e.g., Y-direction), first and second source/drain regions 151 and 152 disposed on the semiconductor pattern 107 on both sides of the gate structure 160, an intermediate insulating pattern 230 disposed between the lower insulating pattern 194L and the semiconductor pattern 107, a vertical insulating pattern 240 penetrating through the substrate insulating layer 194 and in contact with a lower surface of the first source/drain region 151, a first contact structure 250 electrically connected to (e.g., contact) an upper surface of the first source/drain region 151, and a second contact structure 260 electrically connected to (e.g., contact) a lower surface of the second source/drain region 152.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

As used herein, components described as being “electrically connected” are configured such that an electrical signal can be transferred from one component to the other (although such electrical signal may be attenuated in strength as it transferred and may be selectively transferred).

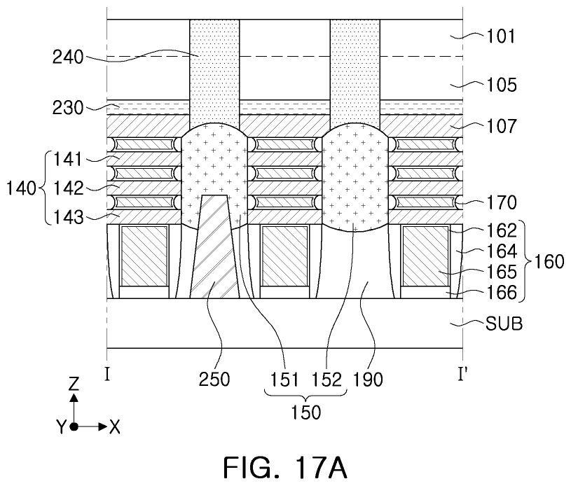

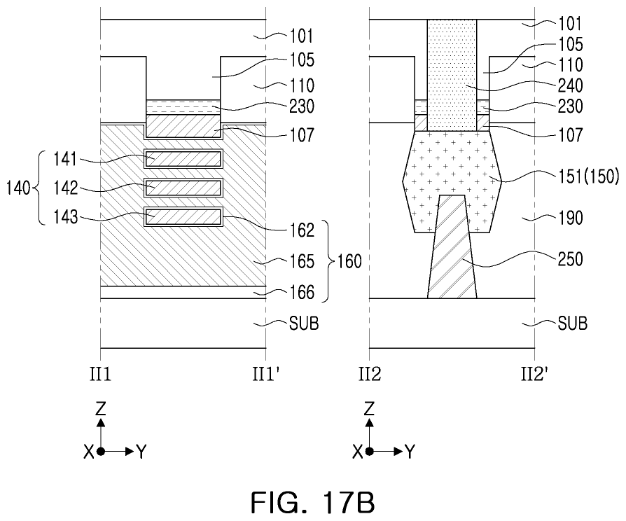

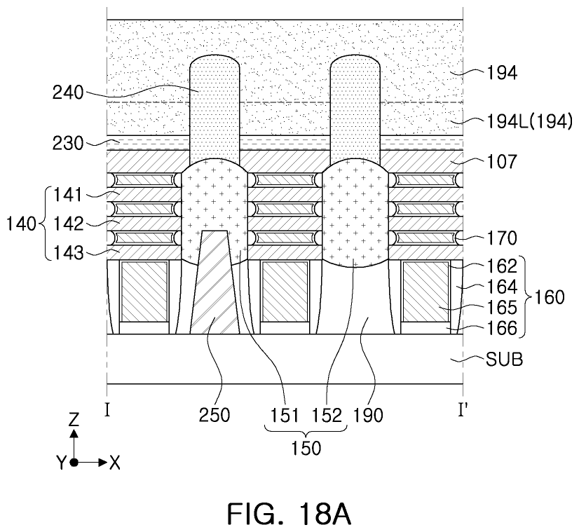

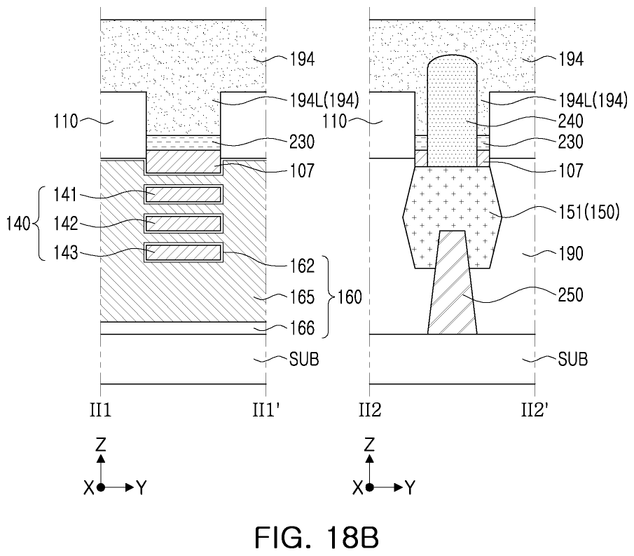

The substrate insulating layer 194 may have an upper/top surface extending in the X-direction and the Y-direction. The substrate insulating layer 194 may be formed by an additional process after removing a substrate formed of a semiconductor material (see 101 and 194 in FIGS. 17A to 18B) during a manufacturing process, or may be formed by oxidizing the semiconductor substrate. The substrate insulating layer 194 may be formed of an insulating material, and may include, for example, an oxide, a nitride, or a combination thereof. In some example embodiments, the substrate insulating layer 194 may include or be formed of a plurality of insulating layers having different materials.

The substrate insulating layer 194 may have a lower insulating pattern 194L protruding from an upper surface and extending (e.g., lengthwise) in the first direction (e.g., X-direction). For example, a portion of the lower insulating pattern 194L may protrude upwards in a vertical direction from the other part of the lower insulating pattern 194L and/or from the other part of the substrate insulating layer 194. The lower insulating pattern 194L may be defined by a fin-type active structure of a semiconductor substrate (see FIGS. 17A to 18B). The lower insulating pattern 194L may have a fin structure protruding from a top surface of the substrate insulating layer 194 in a third direction (e.g., Z-direction).

The intermediate insulating pattern 230 may be disposed on an upper surface of the lower insulating pattern 194L of the substrate insulating layer 194. The intermediate insulating pattern 230 may extend (e.g., lengthwise) in the first direction (e.g., X-direction) similarly to the lower insulating pattern 194L on the lower insulating pattern 194L. The intermediate insulating pattern 230 may have a shape substantially the same as or corresponding to the upper surface of the lower insulating pattern 194L in a plan view. The intermediate insulating pattern 230 employed in the example embodiment will be described in more detail later.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The semiconductor pattern 107 may be disposed on an upper surface of the lower insulating pattern 194L of the substrate insulating layer 194. The semiconductor pattern 107 may extend (e.g., lengthwise) in the first direction (e.g., X-direction) on the lower insulating pattern 194L similarly to the lower insulating pattern 194L. The semiconductor pattern 107 may have a shape substantially the same as or corresponding to the upper surface of the lower insulating pattern 194L in a plan view. The semiconductor pattern 107 may include, for example, at least one of silicon (Si), silicon germanium (SiGe), and germanium (Ge).

The lower insulating pattern 194L, the intermediate insulating pattern 230 and the semiconductor pattern 107 may form a fin-type structure together with the channel structure 140 including a plurality of channel layers 141, 142, and 143. For example, the fin-type structure may have a shape protruding from the top surface of the substrate insulating layer 194 in the third direction (e.g., Z-direction) and extending lengthwise in the first direction (e.g., X-direction). The lower insulating pattern 194L, the intermediate insulating pattern 230 and the semiconductor pattern 107 may be stacked in order in a direction perpendicular to an upper/top surface of the substrate insulating layer 194 (e.g., in the third direction) and may form the fin-type structure (e.g., extending lengthwise in the first direction and protruding from the top surface of the substrate insulating layer 194 in the third direction. The lower insulating pattern 194L, the intermediate insulating pattern 230 and the semiconductor pattern 107 may have the same width in the second direction (e.g., Y-direction). Here, the same width may indicate that the widths in the second direction are not intentionally differently formed from each other, e.g., may be substantially the same which may include process errors.

A device isolation layer 110 may define the fin-type structures 194L, 230, and 107. The device isolation layer 110 may be disposed on the substrate insulating layer 194 to cover at least a portion of a side surface of the semiconductor pattern 107. For example, the device isolation layer 110 may contact the semiconductor pattern 107. The device isolation layer 110 may include or be formed of, for example, an oxide film, a nitride film, or a combination thereof. In some example embodiments, the device isolation layer 110 may include a deep trench isolation (DTI) region (not illustrated) formed to be deeper than a shallow trench isolation STI together with the STI region defining the fin structures 194L, 230, and 107. The device isolation layer 110 may be formed such that an upper region of the fin-type structure, e.g., an upper region of the semiconductor pattern 107 is exposed. In some example embodiments, the device isolation layer 110 may have a curved upper surface having a level increasing in a direction approaching to the semiconductor pattern 107.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The channel structure 140 may be disposed on the substrate insulating layer 194 to intersect the gate structures 160. The channel structure 140 may include first to third channel layers 141, 142, and 143. For example, the channel structure 140 may include two or more channel layers spaced apart from each other in a direction perpendicular to an upper surface of the substrate insulating layer 194. The channel structure 140 may be electrically connected to (e.g., contact) the source/drain regions 150. The channel structure 140 may have a width the same as or similar to that of the gate structure 160 in the first direction (e.g., X-direction). In a cross-section perpendicular to an axis extending in the second direction (e.g., Y-direction), the lower channel layer among the first to third channel layers 141, 142, and 143 may have a width in the first direction equal to or greater than that of the upper channel layer. For example, the width of the first channel layer 141 in the first direction may be the same as or greater than the width of the second channel layer 142 in the first direction, and the width of the second channel layer 142 in the first direction may be the same as or greater than the width of the third channel layer 143 in the first direction. In some example embodiments, the channel structure 140 may have a width in the first direction smaller than a width of the gate structure 160 in the first direction such that side surfaces of the channel structure 140 may be disposed below the gate structure 160. For example, the side surfaces of the channel structure 140 may vertically overlap the gate structure 160. For example, the side surfaces of the channel structure 140 may be side surfaces of the first to third channel layers 141, 142 and 143.

The channel structure 140 may be formed of a semiconductor material, and may include, for example, at least one of silicon (Si), silicon germanium (SiGe), and germanium (Ge). The channel structure 140 may be formed of the same material as that of the semiconductor pattern 107. The number of channel layers included in one channel structure 140 and the shape thereof may vary in different example embodiments.

In the semiconductor device 100A, a gate electrode 165 may be disposed between the first to third channel layers 141, 142, and 143 of the channel structure 140 and on the channel structure 140. Accordingly, the semiconductor device 100A may include a multi-bridge channel FET (MBCFET™) structure transistor, which is a gate-all-around type field effect transistor.

The gate structures 160 may be disposed to extend (e.g., lengthwise) in one direction, for example, the Y-direction, on the substrate insulating layer 194. A channel region of transistors may be formed in the channel structure 140 intersecting the gate electrode 165 of the gate structures 160. The gate structures 160 may be spaced apart from each other in the X-direction. Each of the gate structures 160 may include gate dielectric layers 162, gate spacer layers 164, and gate electrode 165. In example embodiments, each of the gate structures 160 may further include a capping layer 166 on an upper surface of the gate electrode 165.

The gate dielectric layers 162 may be disposed between the semiconductor pattern 107 and the gate electrode 165 and between the channel structure 140 and the gate electrode 165, and may be disposed to cover/contact at least a portion of the surfaces of the gate electrode 165. For example, the gate dielectric layers 162 may be disposed to surround the entirety of surfaces other than an uppermost surface of the gate electrode 165. The gate dielectric layers 162 may extend to a region between the gate electrode 165 and the gate spacer layers 164, but example embodiments are not limited thereto. The gate dielectric layer 162 may include or be formed of oxide, nitride, or high-κ material. The high-κ material may be a dielectric material having a higher dielectric constant than that of silicon oxide (SiO₂). The high-κ material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In example embodiments, the gate dielectric layer 162 may be a multilayer structure.

The gate electrode 165 may include or be formed of a conductive material, for example, metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In example embodiments, the gate electrode 165 may have a multilayer structure. In a region not illustrated in the drawings, the gate electrodes 165 may be electrically connected to (e.g., contact) upper contact plugs disposed thereon.

The gate spacer layers 164 may be disposed on both side surfaces of the gate electrode 165 on the channel structure 140. The gate spacer layers 164 may electrically insulate source/drain regions 150 from gate electrodes 165 and vice versa. In example embodiments, the shape of the upper end of the gate spacer layers 164 may vary, and the gate spacer layers 164 may have a multilayer structure. The gate spacer layers 164 may include or be formed of at least one of oxide, nitride, and oxynitride, and/or may include, for example, a low-K film. The gate capping layer 166 may be disposed on the gate electrode 165, and lower and side surfaces of the gate capping layer 166 may be surrounded by (e.g., contact) the gate electrode 165 and the gate spacer layers 164, respectively.

In an example embodiment, internal spacer layers 170 disposed on both/opposite sides of the gate structure 160 in the first direction (e.g., X-direction) on each of the plurality of channel layers 141, 142, and 143 may be further included. The internal spacer layers 170 may be disposed in parallel with the gate electrode 165 between the plurality of channel layers 141, 142, and 143. The internal spacer layers 170 may be in contact with the gate dielectric layer 162. The internal spacer layers 170 may be disposed between the gate dielectric layer 162 and the source/drain regions 150. Side surfaces of the internal spacer layers 170 may be in contact with the source/drain regions 150. Below each of the plurality of channel layers 141, 142, and 143, the gate electrode 165 may be spaced apart from the source/drain regions 150 by the internal spacer layers 170 and may be electrically isolated from the source/drain regions 150. A side surface of an internal spacer layer 170 facing the gate electrode 165 may have a convex shape protruding toward the gate electrode 165. For example, side surfaces of the gate electrode 165 facing the internal spacer layers 170 may have concave shapes. The internal spacer layers 170 may include or be formed of oxide, nitride, and/or oxynitride, and/or may include a low-k film.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

The internal spacer layers 170 may be formed of the same material as that of the gate spacer layers 164, but example embodiments are not limited thereto. For example, the internal spacer layers 170 may include at least one of SiN, SiCN, SiOCN, SiBCN, and SiBN. The internal spacer layers 170 may also be applied to the other example embodiments.

The source/drain regions 150 may be disposed to be in contact with the channel structures 140 on both sides of the gate structures 160, respectively. The source/drain regions 150 may be disposed on (e.g., contact) the semiconductor pattern 107. A source/drain region 150 may be provided as a source region or a drain region of a transistor. The source/drain regions 150 may include a first source/drain region 151 vertically overlapping the substrate insulating layer 194 and disposed on the substrate insulating layer 194, and a second source/drain region 152 spaced apart from the first source/drain region 151 in the first direction (e.g., X-direction). The second source/drain region 152 may be electrically connected to (e.g., contact) the second contact structure 260, e.g., through a lower surface or a lower end. A lower region/surface of the first source/drain region 151 may have a shape recessed by the vertical insulating pattern 240, and a lower region of the second source/drain region 152 may have a shape recessed by the second contact structure 260. The second source/drain region 152 may be electrically connected to the power transfer structure 265 through the second contact structure 260 and may receive power through the power transfer structure 265 and the second contact structure 260. An upper surface of the source/drain regions 150 may be disposed on a level the same as or lower than a level of a lower surface of the gate electrode 165 on the channel structure 140, and the level may vary in example embodiments.

The source/drain regions 150 may include at least one of semiconductor materials, for example, silicon (Si) and/or germanium (Ge), and may further include impurities.

When the semiconductor device 100 is a pFET, the impurities may be at least one of boron (B), gallium (Ga), and indium (In). In the case of an nFET, the impurities may be phosphorus (P), arsenic (As), and/or antimony (Sb).

The source/drain regions 150 may include epitaxial layers disposed along side surfaces of the first to third channel layers 141, 142, and 143 of the channel structure 140. A source/drain region 150 may include a plurality of epitaxial layers, but example embodiments are not limited thereto. The source/drain region 150 may be a semiconductor layer including silicon (Si) and/or germanium (SiGe). The source/drain regions 150 may include impurities of different types and/or different concentrations. For example, the source/drain regions 150 may include N-type doped silicon (Si) and/or P-type doped silicon germanium (SiGe). In example embodiments, the source/drain regions 150 may include a plurality of regions including different concentrations of elements and/or different doping elements. The source/drain region 150 may have a circular, elliptical, pentagonal, or hexagonal shape, or a similar shape to one of these in a cross-section perpendicular to an axis extending to the X-direction. However, in example embodiments, the source/drain region 150 may have various shapes, for example, one of a polygonal shape, a circular shape, and a rectangular shape.

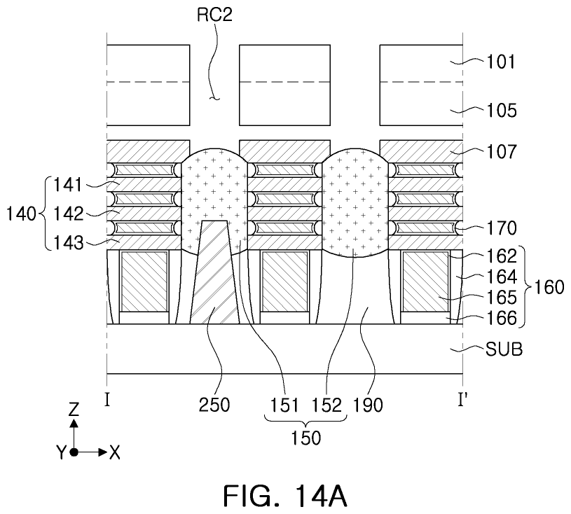

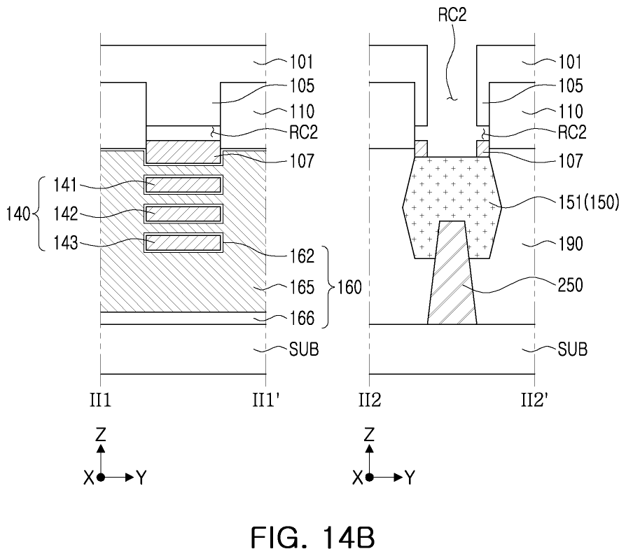

In the example embodiment, the intermediate insulating pattern 230 may extend in the first direction (e.g., X-direction) on the substrate insulating layer 194. The intermediate insulating pattern 230 may be disposed between the lower insulating pattern 194L of the substrate insulating layer 194 and the semiconductor pattern 107. The intermediate insulating pattern 230 may be defined by the device isolation layer 110. The intermediate insulating pattern 230 may be formed of a low-K material, and may be formed of a material having an etch selectivity to silicon (Si). The intermediate insulating pattern 230 may include or be formed of, for example, at least one of SiO, SiN, SiCN, SiOC, SiON, and SiOCN. A lower surface of the intermediate insulating pattern 230 may be disposed on a level lower than a level of a lowermost end of the source/drain regions 150. The intermediate insulating pattern 230 may work as an etch stop layer when the silicon (Si) substrate 101 is removed during a process described later (see FIGS. 17A to 14B) and may prevent the source/drain regions 150 from being etched together with the substrate 101.

The thickness t of the intermediate insulating pattern 230 may be smaller than or equal to a distance d between the plurality of channel layers 141, 142, and 143 of the channel structure 140. In a manufacturing process described later, a thickness t of the intermediate insulating pattern 230 may correspond to (e.g., the same as) a thickness t of the lowermost end sacrificial layer 120L, and a distance d between the plurality of channel layers 141, 142, and 143 may correspond to (e.g., the same as) a thickness d of each of the upper sacrificial layers 120U.

The vertical insulating pattern 240 may penetrate through the lower insulating pattern 194L, the intermediate insulating pattern 230 and the semiconductor pattern 107 of the substrate insulating layer 194 and may extend (e.g., lengthwise) in a direction perpendicular to an upper surface of the substrate insulating layer 194. The vertical insulating pattern 240 may be in contact with a lower surface of the source/drain regions 150. For example, a top surface of the vertical insulating pattern 240 may be at the same height as a top surface of the semiconductor pattern 107, and a bottom surface of the vertical insulating pattern may be at a lower vertical level than a lowermost part of the lower insulating pattern 194L. For example, heights and vertical levels in the present disclosure may be distances in a vertical direction from a horizontal plane, e.g., from a bottom surface of a semiconductor device. The vertical insulating pattern 240 may be formed of an insulating material easily removed by a wet etching process. The vertical insulating pattern 240 may be formed of, for example, AlO.

The vertical insulating pattern 240 may penetrate through a fin structure including the lower insulating pattern 194L, the intermediate insulating pattern 230 and the semiconductor pattern 107 and may extend toward a lower surface of the substrate insulating layer 194. An upper surface of the vertical insulating pattern 240 may be coplanar with an upper surface of the semiconductor pattern 107 and a lower surface of the source/drain region 150. The vertical insulating pattern 240 may extend downwards and penetrate into the substrate insulating layer 194 to a level lower than a level of the lower surface L2 of the device isolation layer 110 such that the lowermost end L1 of the vertical insulating pattern 240 is positioned at the level lower than the level of the lower surface L2 of the device isolation layer 110.

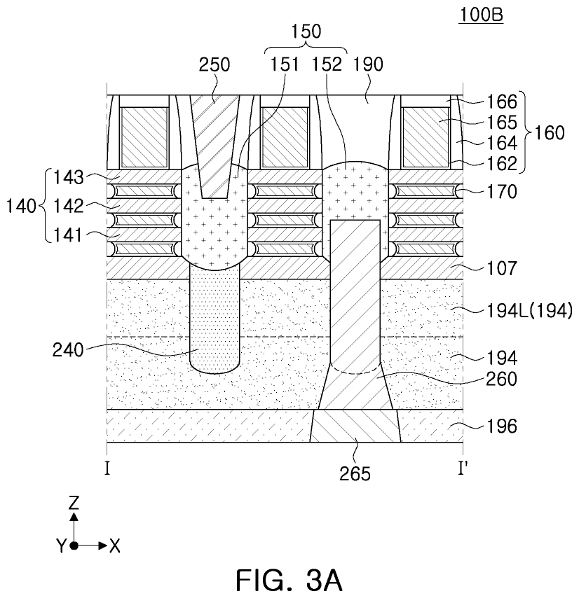

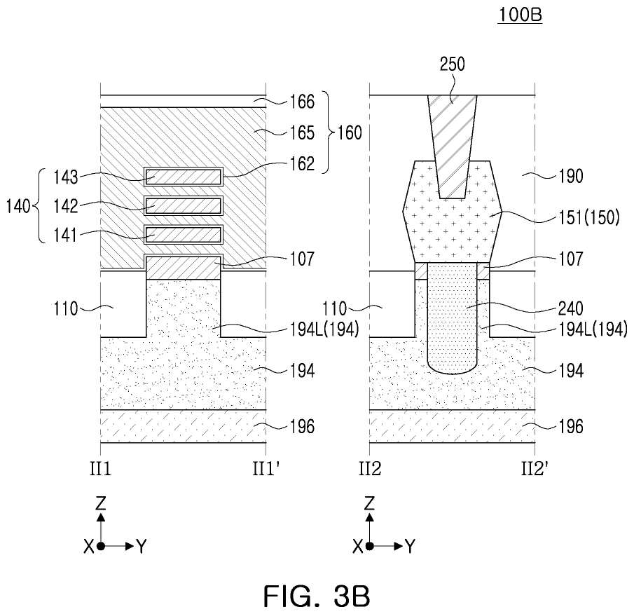

The vertical insulating pattern 240 may be in contact with the source/drain regions 150 (see FIGS. 3A and 3B). The vertical insulating pattern 240 may be a pattern for aligning a backside contact structure 260 to be electrically connected to (e.g., contact) the source/drain regions 150. A width of the vertical insulating pattern 240 in the first direction (e.g., X-direction) may be the same as a width of at least a portion of the backside contact structure 260 in the first direction. The vertical insulating pattern 240 may vertically overlap the first source/drain region 151 and the first contact structure 250 electrically connected to (e.g., contact) an upper surface of the first source/drain region 151. The vertical insulating pattern 240 may be disposed to be spaced apart from the second source/drain region 152 and the second contact structure 260 electrically connected to (e.g., contact) each other below the second source/drain region 152 in the first direction.

The contact structures 250 and 260 may be connected to the source/drain regions 150. According to example embodiment, the contact structures 250 and 260 may include the first contact structure 250 electrically connected to (e.g., contact) the first source/drain region 151 above the first source/drain region 151, and the second contact structure 260 electrically connected to (e.g., contact) the second source/drain region 152 by penetrating through the substrate insulating layer 194 below the second source/drain region 152. The second contact structure 260 may not vertically overlap the first contact structure 250. For example, the second contact structure 260 may be spaced apart from the first contact structure 250 in a horizontal direction (e.g., in the X-direction). In example embodiments, the second contact structure 260 may be referred to as a backside contact structure 260.

The first contact structure 250 may penetrate through at least a portion of the interlayer insulating layer 190, may be in contact with the first source/drain region 151 and may apply an electrical signal to the first source/drain region 151. The first contact structure 250 may be disposed on the first source/drain region 151 and, in example embodiments, the first contact structure 250 may be disposed/formed to have a length longer than that of the first source/drain region 151 in the second direction (e.g., Y-direction), e.g., differently from the ones illustrated in the figures. The first contact structure 250 may have an inclined side surface of which a width of a lower portion may be narrower than a width of an upper portion depending on an aspect ratio, but example embodiments are not limited thereto. The first contact structure 250 may be disposed/formed to be recessed (e.g., penetrate) into the first source/drain region 151 to a predetermined depth. The first contact structure 250 may horizontally overlap the third channel layer 143 which is the uppermost layer of the channel structure 140, or extend to a level below the third channel layer 143 from above the first source/drain region 151. The first contact structure 250 may include metal nitride such as titanium nitride (TiN), tantalum nitride (TaN), or tungsten nitride (WN), and/or a metal material such as aluminum (Al), tungsten (W), or molybdenum (Mo).

A backside contact structure 260 may be disposed below the source/drain regions 150. In an example embodiment, the backside contact structures 260 may be electrically connected to (e.g., contact) the second source/drain region 152 below the second source/drain region 152.

The backside contact structure 260 may penetrate through the substrate insulating layer 194 and may extend (e.g., lengthwise) vertically. A side surface of the backside contact structure 260 and a side surface of the substrate insulating layer 194 may be in contact with each other. The backside contact structure 260 may be formed in a region from which the vertical insulating pattern 240 is removed. The backside contact structure 260 may be a self-align contact (SAC) aligned by the vertical insulating pattern 240. Accordingly, a contact margin between the backside contact structure 260 and the source/drain regions 150 may be assured. The backside contact structure 260 may penetrate through the substrate insulating layer 194 and may be electrically connected to the second source/drain region 152. The backside contact structure 260 may be partially recessed into a lower region of the second source/drain region 152 and may be in contact with the recessed lower surface of the second source/drain region 152. The backside contact structure 260 may be formed to extend to partially penetrate through the second source/drain region 152. For example, the backside contact structure 260 may penetrate into the second source/drain region 152. A level of an upper end (e.g., a top surface) of the backside contact structure 260 may be higher than a level of a lower end (e.g., a bottom surface) of the second source/drain region 152.

The backside contact structure 260 may be formed in a region from which at least one of the vertical insulating patterns 240 is removed. Referring to FIG. 2A, the backside contact structure 260 may include a region (a region indicated by a dotted line in the drawing) from which the vertical insulating pattern 240 is removed and may extend to a lower surface of the substrate insulating layer 194 from the region which the vertical insulating pattern 240 is removed from. A width of a portion of the backside contact structure 260 may be the same as that of the vertical insulating pattern 240 spaced apart from the backside contact structure 260 in a first direction. A width of another portion of the backside contact structure 260 may continuously/gradually increase in a direction approaching a bottom surface of the backside contact structure 260, but example embodiments are not limited thereto.

The power transfer structure 265 may be disposed on a lower surface of the substrate insulating layer 194 and may be connected to (e.g., contact) a lower end or a lower surface of the backside contact structure 260. The power transfer structure 265, together with the backside contact structure 260, may form a BSPDN for applying power or ground voltage, and may be referred to as a backside power rail or a buried power rail. For example, the power transfer structure 265 may be a buried interconnection line extending below the backside contact structure 260 in one direction, for example, in the Y-direction, but the shape of the power transfer structure 265 is not limited thereto. For example, in some example embodiments, the power transfer structure 265 may include via regions and/or line regions. A width of the power transfer structure 265 may continuously/gradually increase in a direction approaching a bottom surface of the power transfer structure 265, but example embodiments are not limited thereto.

The power transfer structure 265 may include or be formed of a conductive material, for example, at least one of tungsten (W), copper (Cu), aluminum (Al), cobalt (Co), ruthenium (Ru), titanium (Ti), and molybdenum (Mo).

The interlayer insulating layer 190 may be disposed to cover/contact the source/drain regions 150, the gate structure 160 and the device isolation layer 110. The interlayer insulating layer 190 may include or be formed of, for example, at least one of oxide, nitride, oxynitride, and low-K dielectric.

The lower insulating layer 196 may be disposed to cover/contact a lower surface of the substrate insulating layer 194 and may surround the power transfer structure 265. The lower insulating layer 196 may include at least one of oxide, nitride, and oxynitride, and may include, for example, a low-K material. In example embodiments, the lower insulating layer 196 may include a plurality of insulating layers.

FIG. 3A is a cross-sectional diagram illustrating a semiconductor device 100B taken along a line corresponding to line I-I′ of FIG. 1 according to an example embodiment. FIG. 3B is cross-sectional diagrams illustrating a semiconductor device taken along lines corresponding to lines II1-II1′ and II2-II2′ of FIG. 1 according to an example embodiment.

Referring to FIGS. 3A and 3B, a semiconductor device 100B in an example embodiment may be the same as or similarly to the examples described with reference to FIGS. 1 to 2B other than the configuration in which the intermediate insulating pattern 230 is removed. The semiconductor device 100B may include a fin-type structure having a protruding fin structure on the substrate insulating layer 194, and the fin-type structure may include a lower insulating pattern 194L extending (e.g., lengthwise) in the first direction (e.g., X-direction) and a semiconductor pattern 107 extending (e.g., lengthwise) in the first direction on the lower insulating pattern 194L. For example, the protruding fin structure may protrude upwardly (e.g., in the Z-direction). The semiconductor device 100B in an example embodiment may be formed by removing the substrate 101 to a level of a lower surface of the intermediate insulating pattern 230 and removing the intermediate insulating pattern 230 (see FIGS. 18A and 18B). Accordingly a lower surface of the semiconductor pattern 107 may be in contact with an upper surface of the lower insulating pattern 194L of the substrate insulating layer 194. The vertical insulating pattern 240 may penetrate through the fin-type structure including the semiconductor pattern 107 and the lower insulating pattern 194L and may extend toward a lower surface of the substrate insulating layer 194. For example, a bottom surface of the vertical insulating pattern 240 may be at a lower level than a bottom of the fin-type structure.

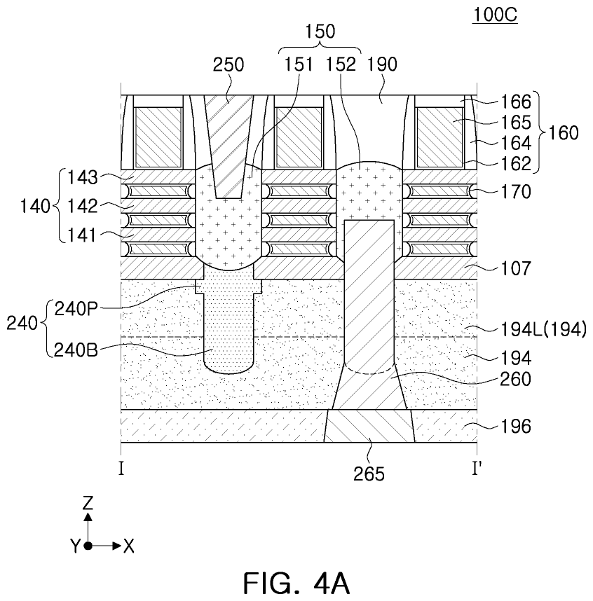

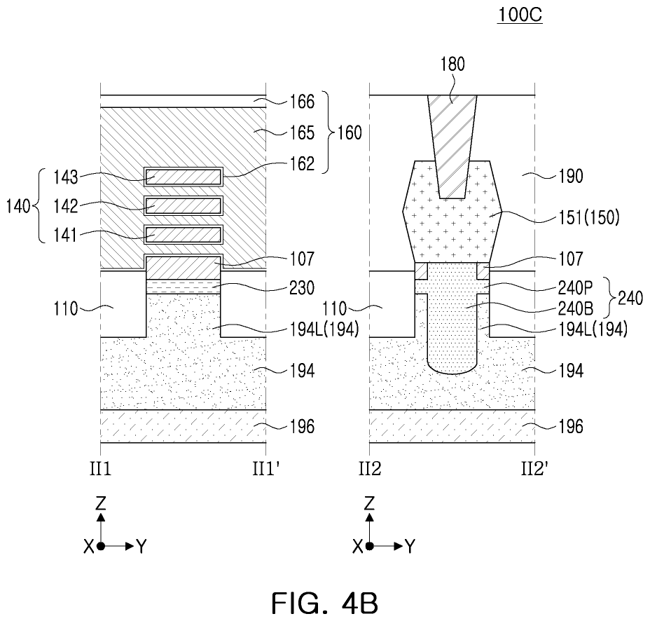

FIG. 4A is a cross-sectional diagram illustrating a semiconductor device 100C taken along a line corresponding to line I-I′ of FIG. 1 according to an example embodiment. FIG. 4B is cross-sectional diagrams illustrating a semiconductor device taken along lines corresponding to lines II1-II1′ and II2-II2′ of FIG. 1 according to an example embodiment.

Referring to FIGS. 4A and 4B, a semiconductor device 100C in an example embodiment may be the same as or similarly to the examples described with reference to FIGS. 1 to 3B, other than that the intermediate insulating pattern 230 is removed and the vertical insulating pattern 240 includes a protrusion 240P and a body portion 240B. The semiconductor device 100C may include a body portion 240B penetrating through the substrate insulating layer 194 and extending downwards from a lower/bottom surface of the source/drain regions 150 to a level lower than a lower/bottom surface of the device isolation layer 110, and a vertical insulating pattern 240 having a protrusion 240P disposed on a level higher than a level of a lower/bottom surface of the device isolation layer 110.

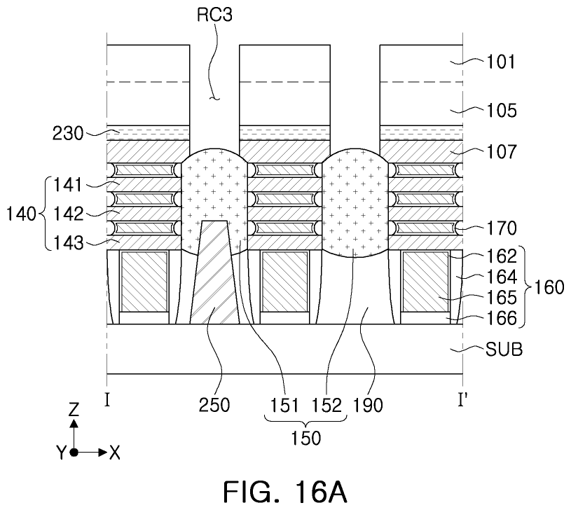

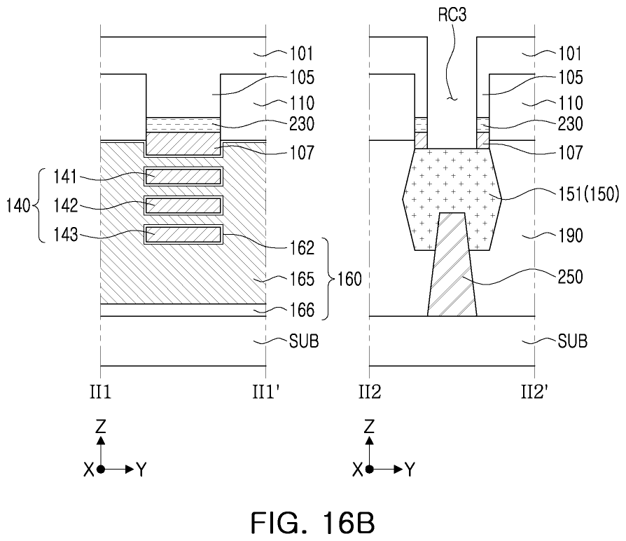

Referring to FIGS. 16A and 16B in addition to FIGS. 4A and 4B, a portion of the preliminary intermediate insulating pattern 230p may be further etched such that a third recess region RC3 may extend horizontally, e.g., as shown in FIG. 4B and the intermediate insulating pattern 230 may be reduced. A third recess region RC3 may be partially further formed below the semiconductor pattern 107, e.g., as shown in FIG. 4B.

Referring to FIGS. 17A and 17B in addition to FIGS. 4A and 4B, a vertical insulating pattern 240 may be formed in the horizontally extended third recess region RC3. For example, the vertical insulating pattern 240 may include a body portion 240B penetrating into the substrate insulating layer 194 and extending vertically from a lower/bottom surface of the source/drain regions 150 toward a lower/bottom surface of the substrate insulating layer 194, and a protrusion 240P surrounding at least a portion of a side surface of the body portion. For example, the protrusion 240P may have a ring shape. For example, the protrusion 240P may be formed in the horizontally extended third recess region RC3. A thickness of the protrusion 240P of the vertical insulating pattern 240, e.g., in a vertical direction, may be the same as a thickness t of the intermediate insulating pattern 230 in the vertical direction shown in FIG. 2A. The thickness of the protrusion 240P of the vertical insulating pattern 240 may be equal to or smaller than a distance d between the plurality of channel layers in the vertical direction illustrated in FIG. 2A. The protrusion 240P of the vertical insulating pattern 240 may be in contact with a side surface of the intermediate insulating pattern 230. The body portion 240B of the vertical insulating pattern 240 of the semiconductor device 100C in an example embodiment may correspond to (e.g., be the same as) the vertical insulating pattern 240 of the semiconductor device 100A in an example embodiment, e.g., shown in FIGS. 2A and 2B.

Referring to FIGS. 4A, 4B, 18A and 18B, in the semiconductor device 100C in an example embodiment, an intermediate insulating pattern 230 may be removed. A process of removing the intermediate insulating pattern 230 and a structure of the example embodiment after the removal may be the same as or similar to the examples described above with respect to FIGS. 3A and 3B.

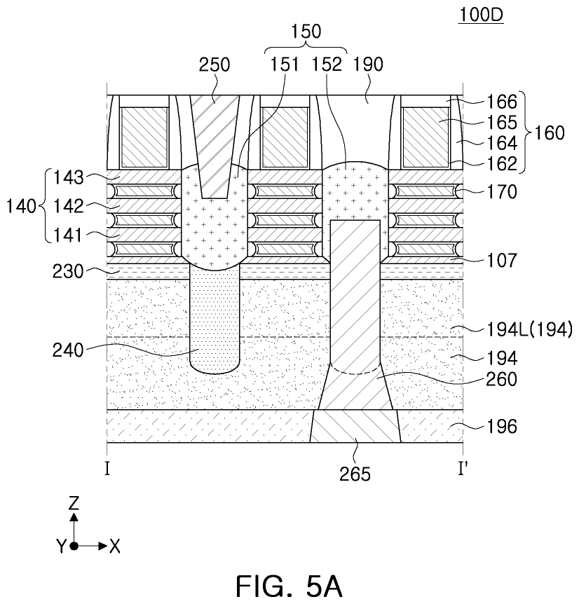

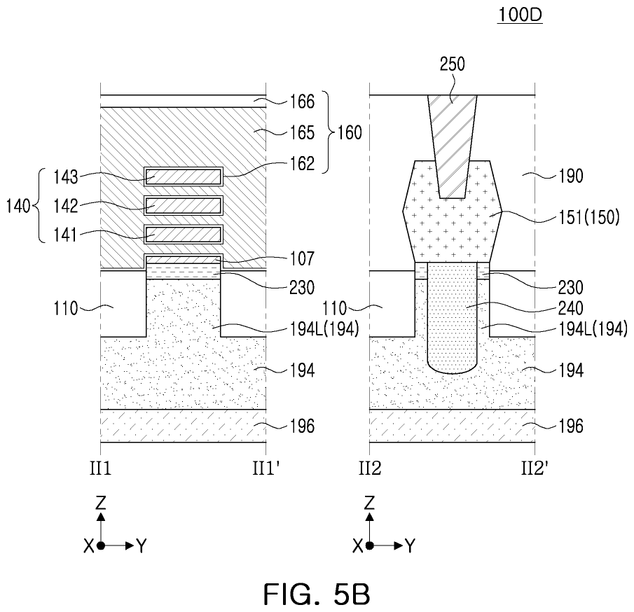

FIG. 5A is a cross-sectional diagram illustrating a semiconductor device 100D taken along a line corresponding to line I-I′ of FIG. 1 according to an example embodiment. FIG. 5B is cross-sectional diagrams illustrating a semiconductor device taken along lines corresponding to lines II1-II1′ and II2-II2′ of FIG. 1 according to an example embodiment.

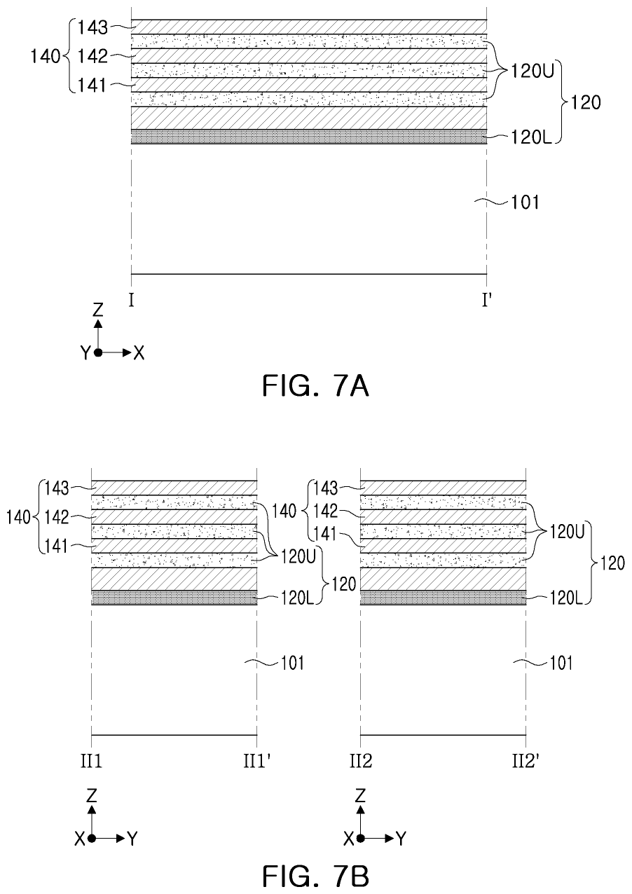

Referring to FIGS. 5A and 5B, the semiconductor device 100D in an example embodiment may be the same as or similarly to any of the examples described with reference to FIGS. 1 to 4B, other than the configuration in which an uppermost end of the intermediate insulating pattern 230 may be disposed on the same level as a level of the uppermost end of the vertical insulating pattern 240. In the semiconductor device 100D, the uppermost end of the intermediate insulating pattern 230 may be disposed on the same level as a level of the uppermost end of the vertical insulating pattern 240 and the lowermost end of the source/drain region 150. Referring to FIGS. 7A and 7B, by varying the distance at which the lowermost end sacrificial layer 120L is isolated from the upper sacrificial layers, a semiconductor device 100D according to an example embodiment may be formed. The semiconductor pattern 107 may extend in the first direction (e.g., X-direction) on the intermediate insulating pattern 230, but may include a plurality of regions in which portions thereof may be isolated/separated from each other below the source/drain regions 150. For example, the source/drain regions may be disposed between portions of and horizontally overlap the semiconductor pattern 107.

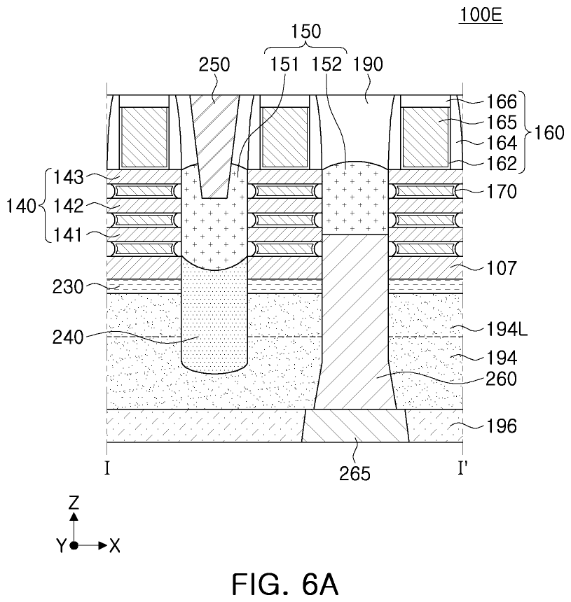

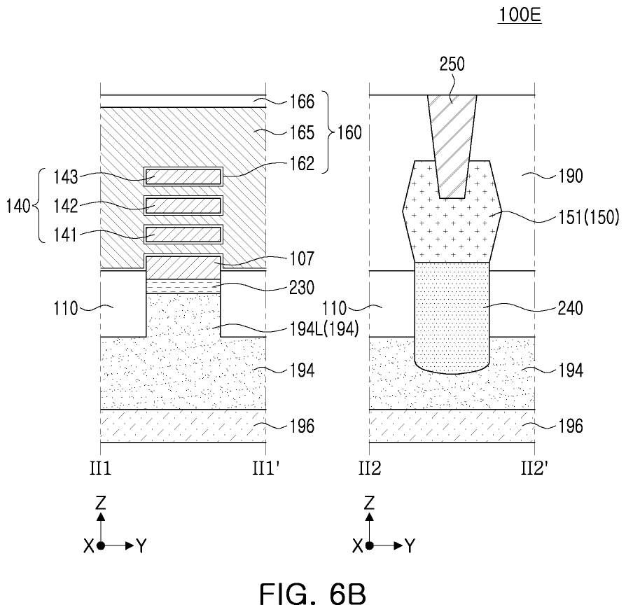

FIG. 6A is a cross-sectional diagram illustrating a semiconductor device 100E taken along a line corresponding to line I-I′ of FIG. 1 according to an example embodiment. FIG. 6B is cross-sectional diagrams illustrating a semiconductor device taken along lines corresponding to lines II1-II1′ and II2-II2′ of FIG. 1 according to an example embodiment.

Referring to FIGS. 6A and 6B, the semiconductor device 100E in an example embodiment may be the same as or similarly to any of the examples described with reference to FIGS. 1 to 5B, other than the configuration in which a width of the vertical insulating pattern 240 in the second direction (e.g., Y-direction) is equal to a width of the intermediate insulating pattern 230 in the second direction. A width of the vertical insulating pattern 240 in the first direction may be the same as that of the source/drain regions 150 in the first direction. A width of the vertical insulating pattern 240 in the second direction (e.g., Y-direction) may be the same as a width of the lower surface of the source/drain regions 150 in the second direction. In an example embodiment, the semiconductor pattern 107 and the intermediate insulating pattern 230 may have a plurality of regions spaced apart from each other in the first direction. For example, the plurality of regions of the semiconductor pattern 107 and the intermediate insulating pattern 230 may be separated by the vertical insulating pattern 240 and the second contact structure 260 interposed therebetween in the first direction (X-direction).

FIGS. 7A to 12B are cross-sectional diagrams illustrating a method of manufacturing a semiconductor device, e.g., a portion of processes of forming a semiconductor device (processes of forming a source/drain region and a gate structure) according to an example embodiment, and FIGS. 13A to 18B are cross-sectional diagrams illustrating a method of manufacturing a semiconductor device, e.g., another portion of processes of forming a semiconductor device (processes of forming an intermediate insulating pattern and a backside contact structure) according to an example embodiment. For example, FIGS. 7A to 12B are cross-sectional diagrams illustrating a frontside process, and FIGS. 13A to 18B are cross-sectional diagrams illustrating a backside process.

First, referring to FIGS. 7A and 7B, sacrificial layers 120 and first to third channel layers 141, 142, and 143 may be alternately stacked on a substrate 101.

The substrate 101 may include or be formed of silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The sacrificial layers 120 may include a plurality of upper sacrificial layers 120U and a lowermost end sacrificial layer (e.g., a lowermost sacrificial layer) 120L spaced apart from each other in a direction perpendicular to an upper surface of the substrate 101 (e.g., in a vertical direction). The upper sacrificial layers 120U may be replaced by gate dielectric layers 162 and gate electrodes 165 disposed below the third channel layer 143 through a subsequent process, as illustrated in FIGS. 2A and 2B, and the lowermost end sacrificial layer 120L may be replaced with an intermediate insulating pattern 230 through a subsequent process, as illustrated in FIGS. 2A and 2B. The sacrificial layers 120 may be formed of a material having etching selectivity with respect to the first to third channel layers 141, 142, and 143, respectively. The first to third channel layers 141, 142, and 143 may include materials different from that of the sacrificial layers 120. The sacrificial layers 120 and first to third channel layers 141, 142, and 143 may include, for example, a semiconductor material including at least one of silicon (Si), silicon germanium (SiGe), and germanium (Ge), or may include different materials, and may or may not include impurities. For example, the sacrificial layers 120 may include or be formed of silicon germanium (SiGe), and the first to third channel layers 141, 142, and 143 may include or be formed of silicon (Si). In an example embodiment, the lowermost end sacrificial layer 120L may have a higher content of germanium (Ge) than that of the upper sacrificial layers 120U, but example embodiments are not limited thereto.

The sacrificial layers 120 and the first to third channel layers 141, 142, and 143 may be formed by performing an epitaxial growth process from the stack structure. The number of layers of the channel layers alternately stacked with the sacrificial layers 120 may vary in example embodiments. The lowermost end sacrificial layer 120L may be referred to as a first sacrificial layer 120L, and the upper sacrificial layers 120U may be referred to as second sacrificial layers 120U.

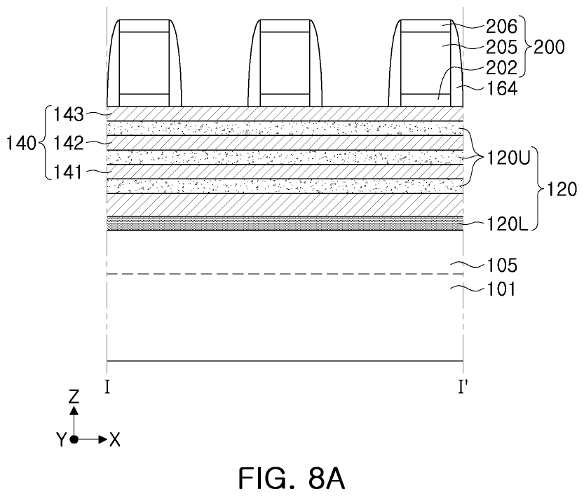

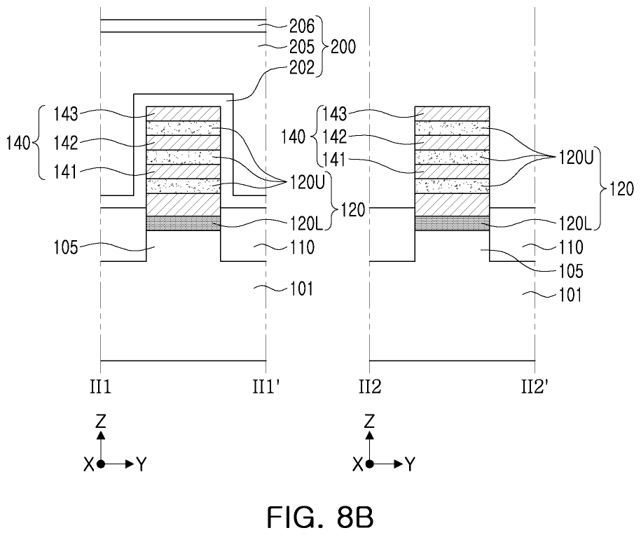

Subsequently, referring to FIGS. 8A and 8B, a preliminary fin-type structure may be formed by partially removing the sacrificial layers 120, the first to third channel layers 141, 142, and 143, and the substrate 101, a device isolation layer 110 may be formed, and sacrificial gate structures 200 and gate spacer layers 164 may be formed on the preliminary fin-type structure.

The preliminary fin-type structure may include an active pattern 105, sacrificial layers 120, and first to third channel layers 141, 142, and 143. The preliminary fin-type structure may be formed in a line shape extending (e.g., lengthwise) in one direction, for example, the X-direction, and may be spaced apart from an adjacent preliminary fin-type structure in the Y-direction. Each of side surfaces of the preliminary fin-type structure in the Y-direction may be on a plane. For example, layers of the preliminary fin-type structure may be coplanar with each other and may be disposed/aligned on a straight line, e.g., in a vertical direction and/or in the first direction (X-direction), e.g., in a cross-sectional view and/or in a plan view.

In the region in which a portion of each of the active pattern 105, the sacrificial layers 120, and the first to third channel layers 141, 142, and 143 are removed, an insulating material may be filled therein and a portion of the insulating material may be removed such that the active pattern 105 may protrude, thereby forming the device isolation layer 110. An upper surface of the device isolation layer 110 may be formed/positioned on a level lower than a level of an upper surface of the active pattern 105.

The sacrificial gate structure 200 may be a sacrificial structure formed in a region in which the gate dielectric layer 162 and the gate electrode 165 are disposed on the channel structures 140 as illustrated in FIG. 2 through a subsequent process. The sacrificial gate structure 200 may have a line shape extending in one direction intersecting the fin-type structure. The sacrificial gate structures 200 may extend, for example, lengthwise in the Y-direction and may be spaced apart from each other in the X-direction.

The sacrificial gate structure 200 may include first and second sacrificial gate layers 202 and 205 and a mask pattern layer 206 stacked in order. The first and second sacrificial gate layers 202 and 205 may be patterned using a mask pattern layer 206. The first and second sacrificial gate layers 202 and 205 may be an insulating layer and a conductive layer, respectively, but example embodiments are not limited thereto, and the first and second sacrificial gate layers 202 and 205 may be configured as an integrated layer (e.g., as one body/layer). For example, the first sacrificial gate layer 202 may include or be formed of silicon oxide, and the second sacrificial gate layer 205 may include or be formed of polysilicon. The mask pattern layer 206 may include or be formed of silicon oxide and/or silicon nitride.

Gate spacer layers 164 may be formed on both sidewalls of the sacrificial gate structures 200. The gate spacer layers 164 may be formed of a low-K material, and may include or be formed of, for example, at least one of SiO, SiN, SiCN, SiOC, SiON, and SiOCN.

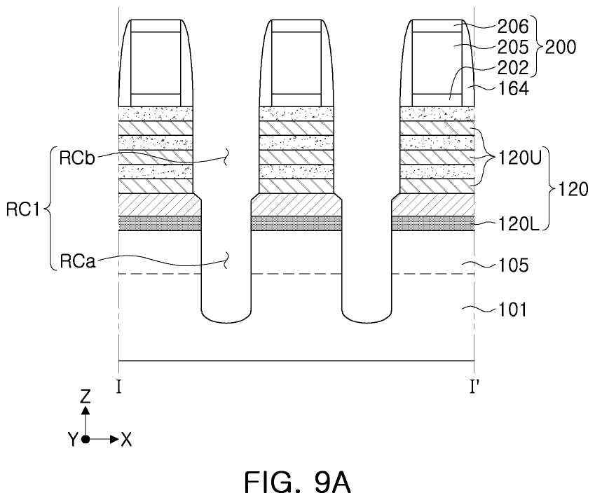

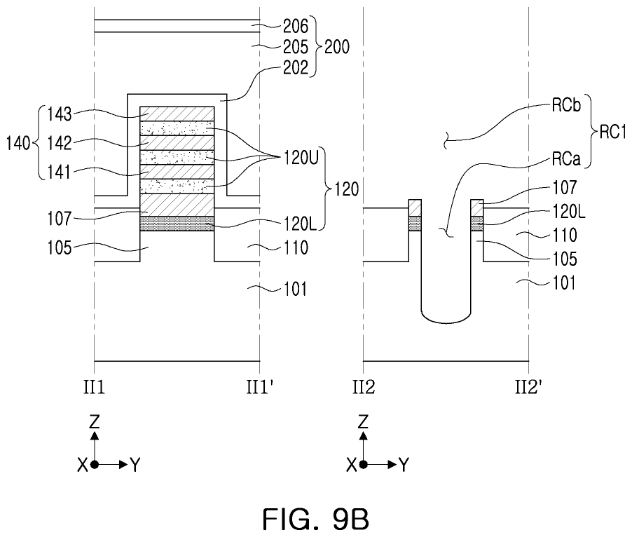

Thereafter, referring to FIGS. 9A and 9B, first recess regions RC1 may be formed by partially removing the substrate 101, the sacrificial layers 120 and the first to third channel layers 141, 142, and 143 exposed from the sacrificial gate structures 200, and a portion of the sacrificial layers 120 may be removed.

A first recess regions RC1 may be formed by removing a portion of exposed substrate 101, a portion of sacrificial layers 120 and a portion of first to third channel layers 141, 142, and 143 using the sacrificial gate structures 200 and the gate spacer layers 164 as a mask. Accordingly, the first to third channel layers 141, 142, and 143 may form channel structures 140 having a limited length in the X-direction.

The sacrificial layers 120 may be selectively etched with respect to the channel structures 140 by, for example, a wet etching process, and may be removed to a predetermined depth in a vertical direction from a side surface of the gate spacer layer 164 in the X-direction. The sacrificial layers 120 may have inwardly curved (e.g., concave) side surfaces by etching the side surface as described above, but example embodiments are not limited thereto.

The first recess regions RC1 may include first lower recess regions RCa and first upper recess regions RCb. The first lower recess regions RCa may be a portion extending downwards from the first upper recess regions RCb toward a lower/bottom surface of the substrate 101. The first lower recess regions RCa may extend downwards toward the lower/bottom surface of the substrate 101 to a level lower than a level of the lower/bottom surface of the device isolation layer 110. In the first direction (e.g., X-direction), the width of the first upper recess regions RCb may be wider than the width of the first lower recess regions RCa, but example embodiments are not limited thereto.

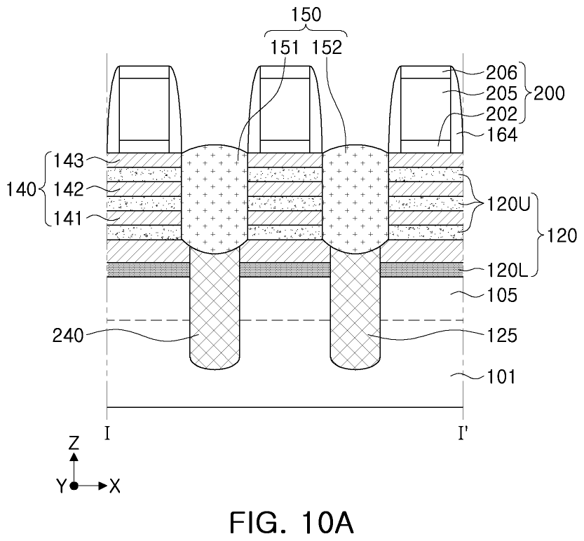

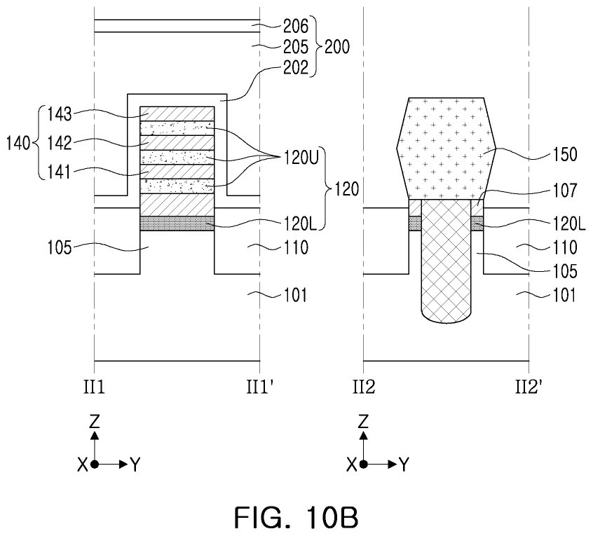

Subsequently, referring to FIGS. 10A and 10B, the sacrificial vertical patterns 125 and the source/drain regions 150 may be formed in the first recess regions RC1.

The sacrificial vertical patterns 125 may be formed such that the lowermost end of the sacrificial vertical patterns 125 may extend to a level lower than a level of the lower surface of the device isolation layer 110. The sacrificial vertical patterns 125 may be formed by filling the first lower recess regions RCa with a semiconductor material including or formed of at least one of silicon (Si), silicon germanium (SiGe), and germanium (Ge). In an example embodiment, the sacrificial vertical patterns 125 may include silicon germanium (SiGe), and a content of germanium of the sacrificial vertical patterns 125 may be equal to a content of germanium of the lowermost end sacrificial layer 120L.

The source/drain regions 150 may be formed by an appropriate epitaxial growth process in a region remaining after forming the sacrificial vertical patterns 125 in the first recess regions RC1, e.g., in the first upper recess regions RCb. The source/drain regions 150 may be formed by epitaxial growth and may extend upwards from top surfaces of the sacrificial vertical patterns 125 to be in contact with the plurality of channel layers 141, 142, and 143 and the sacrificial layers 120 (e.g., the second sacrificial layers 120U) in the first recess region RC1. The source/drain regions 150 may include impurities by in-situ doping.

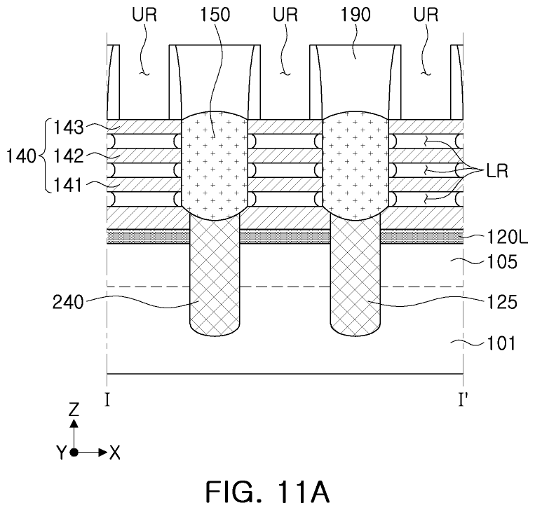

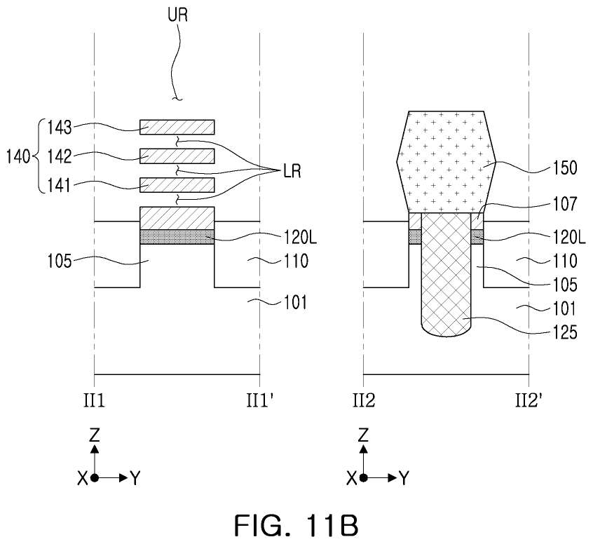

Subsequently, referring to FIGS. 11A and 11B, an interlayer insulating layer 190 may be formed, and upper gap regions UR and lower gap regions LR may be formed by removing the second sacrificial layers 120U and the sacrificial gate structures 200.

The interlayer insulating layer 190 may be formed by forming an insulating film covering the sacrificial gate structures 200 and the source/drain regions 150 and performing a planarization process. The second sacrificial layers 120U and the sacrificial gate structure 200 may be selectively removed with respect to the gate spacer layers 164, the interlayer insulating layer 190, and the channel layers 141, 142, and 143. First, the upper gap regions UR may be formed by removing the sacrificial gate structures 200 together with the mask pattern layer 206, and lower gap regions LR may be formed by removing the second sacrificial layers 120U exposed through the upper gap regions UR. For example, when the second sacrificial layers 120U include silicon germanium (SiGe) and the channel structure 140 include silicon (Si), the second sacrificial layers 120U may be selectively removed by performing a wet etching process using peracetic acid as an etchant. The lowermost end sacrificial layer 120L and the sacrificial vertical patterns 125 may have a content of germanium (Ge) different than that of the second sacrificial layers 120U, and a process of selectively etching only the second sacrificial layers 120U may be performed using/utilizing the difference. During the removal process, the source/drain regions 150 may be protected by the interlayer insulating layer 190.

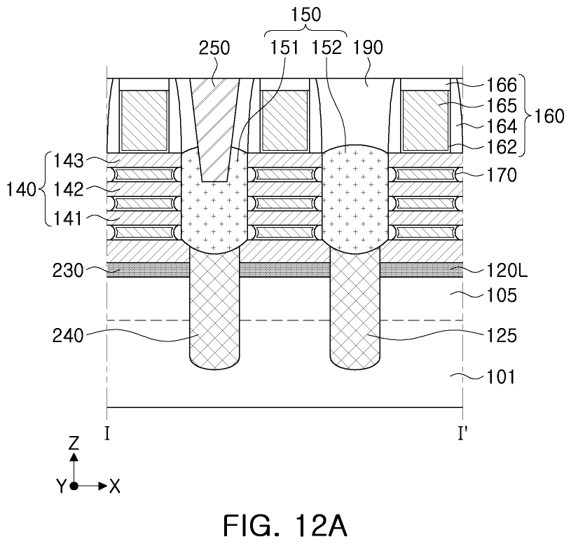

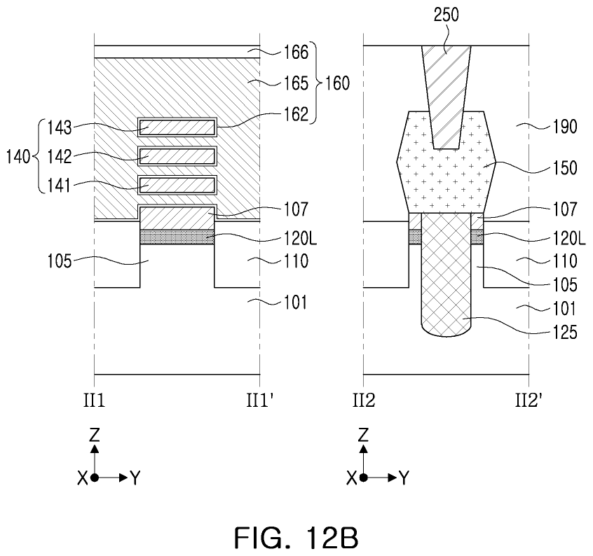

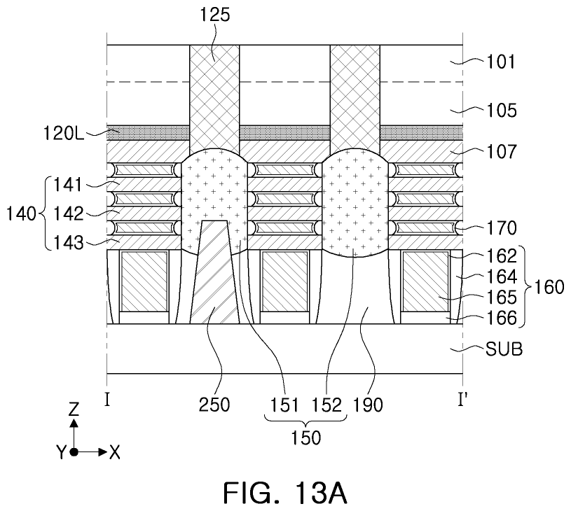

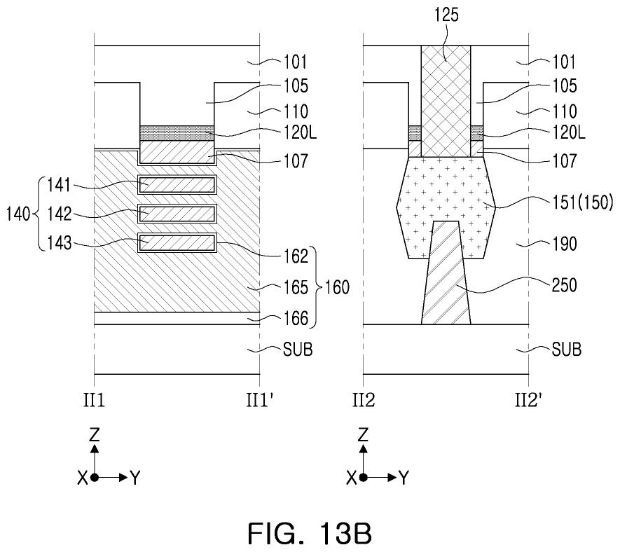

Subsequently, referring to FIGS. 12A and 12B, gate structures 160 may be formed by forming gate dielectric layers 162 and a gate electrode 165, and a first contact structure 250 electrically connected to (e.g., contact) the first source/drain region 151 may be formed by penetrating through the interlayer insulating layer 190.

The gate dielectric layers 162 may be formed to conformally cover internal surfaces of the upper gap regions UR and the lower gap regions LR. The gate electrode 165 may be formed to completely bury/fill the upper gap regions UR and the lower gap regions LR, the gate electrode 165 may be removed from an upper portion to a predetermined depth in the upper gap regions UR. In the upper gap regions UR, a gate capping layer 166 may be formed in a region from which the gate electrodes 165 are removed. Through these processes, the gate structures 160 including the gate dielectric layers 162, the gate electrode 165, the gate spacer layers 164, and the gate capping layer 166 may be formed.

The first contact structure 250 may be formed by forming a contact hole connected to the first source/drain region 150 to penetrate through the interlayer insulating layer 190 and filling the contact hole with a conductive material. A lower surface of the contact hole may be recessed into the first source/drain region 151 or may have a curve along an upper surface of the first source/drain region 151.

First, referring to FIGS. 13A and 13B, the entire structure formed with reference to FIGS. 7A to 12B may be attached to a carrier substrate SUB, and the substrate 101 may be thinned to expose the lower surface of the sacrificial vertical pattern 125.

A carrier substrate SUB may be attached to the entire structure (e.g., to the entire top surface) to perform a process on the lower/bottom surface of the substrate 101 in FIGS. 12A and 12B. In the diagrams from 13A to 18B, and as described below, for ease of understanding, the entire structure may be rotated or reversed in the form of a mirror image of the structure, e.g., illustrated in FIGS. 8A to 12B.

The sacrificial vertical pattern 125 may include or be formed of silicon germanium (SiGe), and the substrate 101 may include or be formed of silicon (Si). Since the substrate 101 has a different etch rate than and/or etching selectivity with respect to the sacrificial vertical pattern 125, the process of thinning the substrate 101 may be selectively performed until the sacrificial vertical pattern 125 is exposed.

Thereafter, referring to FIGS. 14A and 14B, a second recess region RC2 may be formed by removing the sacrificial vertical pattern 125 and the first sacrificial layer 120L from a lower surface of the exposed sacrificial vertical insulating pattern.

The sacrificial vertical pattern 125 and the first sacrificial layer 120L may be formed of silicon germanium (SiGe) and may include germanium (Ge) having the same content. Here, the configuration in which the content may be “the same” may include process errors, and may indicates that the contents of germanium may not be intended/configured to be different. Since the sacrificial vertical pattern 125 and the first sacrificial layer 120L have different etch rate and/or etching selectivity from that of the substrate 101 formed of silicon (Si), the etching process may be selectively performed only for the sacrificial vertical pattern 125 and the first sacrificial layer 120L. The sacrificial vertical pattern 125 and the first sacrificial layer 120L may be removed and a second recess region RC2 may be formed. The second recess region RC2 may be a region including a third recess region RC3 described later and a horizontal isolation space from which the first sacrificial layer 120L is removed. For example, the horizontal isolation space may be a space formed by removing the first sacrificial layer 120L.

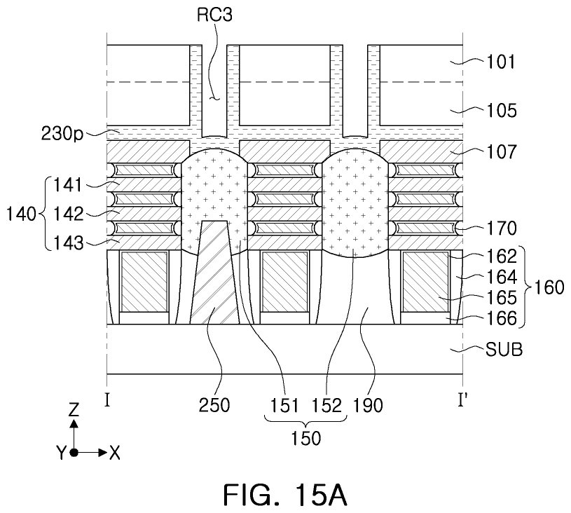

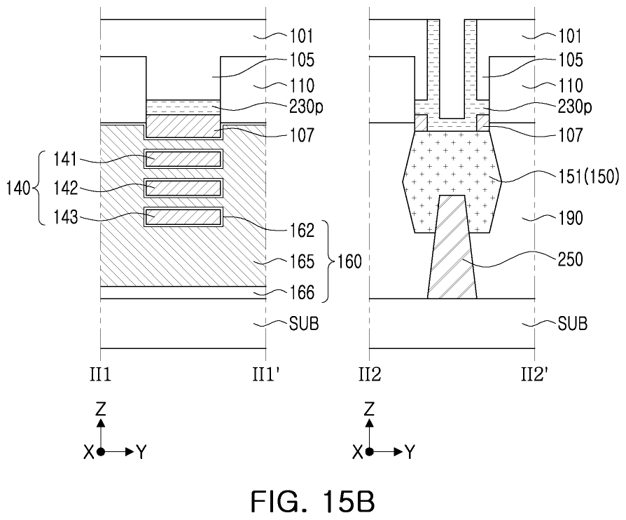

Thereafter, referring to FIGS. 15A and 15B, a preliminary intermediate insulating pattern 230p may be formed in the second recess region RC2.

The preliminary intermediate insulating pattern 230p may be formed in a horizontal isolation space from which the lowermost end sacrificial layer 120L is removed and a portion of a region from which the sacrificial vertical pattern 125 is removed. The preliminary intermediate insulating pattern 230p may be formed along the external side of the region from which the sacrificial vertical pattern 125 is removed. For example, the preliminary intermediate insulating pattern 230p may be formed along a surface of the source/drain regions 150 and a surface of the substrate 101 in the second recess region RC2. The preliminary intermediate insulating pattern 230p may be formed of a low-K material, and may be formed of a material having an etching selectivity from silicon (Si). The preliminary intermediate insulating pattern 230p may include or be formed of, for example, at least one of SiO, SiN, SiCN, SiOC, SiON, and SiOCN.

Subsequently, referring to FIGS. 16A and 16B, an intermediate insulating pattern 230 and a third recess region RC3 may be formed by removing a portion of the preliminary intermediate insulating pattern 230p.

A portion of the preliminary intermediate insulating pattern 230p, present in the horizontal isolation space, may remain, and a portion disposed on a surface of second recess region RC2 may be removed. Among the preliminary intermediate insulating pattern 230p, a portion remaining in the horizontal isolation space may be referred to as an intermediate insulating pattern 230. As a portion of the preliminary intermediate insulating pattern 230p is removed, a void space may be formed and the formed void space may be referred to as a third recess region RC3. The intermediate insulating pattern 230 may be disposed between the active pattern 105 and the semiconductor pattern 107 and may extend in the first direction (e.g., X-direction). The third recess region RC3 may penetrate through the active pattern 105, the intermediate insulating pattern 230 and the semiconductor pattern 107 and may extend in a direction perpendicular to the upper surface of the substrate 101. The third recess region RC3 may expose a lower surface of source/drain regions 150.

Subsequently, referring to FIGS. 17A and 17B, vertical insulating patterns 240 may be formed in third recess regions RC3.

The vertical insulating patterns 240 may be formed to entirely fill the third recess region, and may be spaced apart from each other in the first direction (e.g., X-direction). The vertical insulating patterns 240 may be formed to penetrate through the semiconductor pattern 107, the intermediate insulating pattern 230 and the active pattern 105. The vertical insulating patterns 240 may be in contact with a lower surface of the source/drain regions 150. The vertical insulating patterns 240 may be formed of an insulating material which may be easily removed by a wet etching process. The vertical insulating patterns 240 may be formed of, for example, AlO. The vertical insulating patterns 240 may be formed to have the above-described characteristics.

Subsequently, referring to FIGS. 18A and 18B, the substrate 101 may be removed and a substrate insulating layer 194 may be formed.

The substrate 101 may be removed from an upper surface of the substrate 101, e.g., while the carrier substrate SUB is attached to a surface opposite the upper surface and positioned at a bottom. The substrate 101 may be removed and thinned by, for example, a lapping, grinding, and/or polishing process, and the remaining region may also be removed by an etching and/or oxidation process. In the example embodiments, to address the issue in which a portion of the source/drain regions 150 may be removed in the process of removing the substrate 101 since the source/drain regions 150 include the same material as the substrate 101, intermediate insulating pattern 230 provided as an etch stop layer may be formed on the substrate 101. As the level on which the intermediate insulating pattern 230 is disposed and the thickness of the intermediate insulating pattern 230 are adjusted/optimized, the degree to which the substrate 101 is removed and the degree to which the semiconductor pattern 107 remains may be adjusted/optimized. A substrate insulating layer 194 may be formed in a region from which the substrate 101 is removed. A lower insulating pattern 194L of the substrate insulating layer 194 may be formed in a region from which the active pattern 105 is removed, and a fin-type structure in which a lower insulating pattern 194L, an intermediate insulating pattern 230 and a semiconductor pattern 107 are stacked in order may be formed.

Thereafter, referring to FIGS. 2A and 2B together, the vertical insulating patterns 240 in contact with the second source/drain region 152 may be removed, and a backside contact structure 260 and a power transfer structure 265 may be formed. The backside contact structure 260 may be formed by the same manufacturing process as the process of forming the first contact structure 250. Accordingly, the semiconductor device 100A in FIGS. 2A and 2B may be manufactured.

According to the aforementioned example embodiments, in the semiconductor device, a substrate etch stop layer may be provided in a process of forming a backside contact structure, loss of source/drain regions disposed on the etch stop layer may be reduced, such that electrical properties and reliability may be improved.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the example embodiments have been illustrated and described above, it will be apparent to those skilled in the art that modifications and variations may be made without departing from the scope in the example embodiment as defined by the appended claims.

What is claimed is:

1. A semiconductor device, comprising:
a substrate insulating layer having a lower insulating pattern protruding from an upper surface of the substrate insulating layer and extending in a first direction;
a semiconductor pattern extending on the lower insulating pattern of the substrate insulating layer in the first direction;
a plurality of channel layers stacked on the semiconductor pattern and spaced apart from each other in a direction perpendicular to the upper surface of the substrate insulating layer;
a gate structure intersecting the semiconductor pattern, extending in a second direction crossing the first direction, and surrounding the plurality of channel layers;
first and second source/drain regions disposed on the semiconductor pattern on both sides of the gate structure and electrically connected to the plurality of channel layers;
an intermediate insulating pattern disposed between the lower insulating pattern and the semiconductor pattern and having a thickness equal to or less than a distance between the plurality of channel layers;
a vertical insulating pattern penetrating the substrate insulating layer, the intermediate insulating pattern and the semiconductor pattern and in contact with a lower surface of the first source/drain region;
a first contact structure connected to an upper surface of the first source/drain region; and
a second contact structure penetrating through the substrate insulating layer, the intermediate insulating pattern and the semiconductor pattern and contacting a lower surface of the second source/drain region.

2. The semiconductor device of claim 1, wherein the vertical insulating pattern overlaps at least a portion of the first contact structure in a vertical direction and is spaced apart from the second contact structure in the second direction.

3. The semiconductor device of claim 1, wherein a lower surface of the intermediate insulating pattern is disposed on a level lower than a level of a lowermost end of the first and second source/drain regions.

4. The semiconductor device of claim 1, wherein a width of the intermediate insulating pattern in the second direction is equal to a width of the semiconductor pattern in the second direction.

5. The semiconductor device of claim 1, wherein an uppermost end of the second contact structure is disposed on a level higher than a level of an uppermost end of the vertical insulating pattern.

6. The semiconductor device of claim 1, further comprising:
internal spacer layers disposed between portions of the gate structure disposed between the plurality of channel layers and the first and second source/drain regions.

7. The semiconductor device of claim 1,
a device isolation layer disposed on the substrate insulating layer and defining the lower insulating pattern and the semiconductor pattern,
wherein the vertical insulating pattern extends to a level lower than a level of a lower surface of the device isolation layer.

8. The semiconductor device of claim 7, wherein a side surface of the vertical insulating pattern is in contact with the device isolation layer.

9. The semiconductor device of claim 1, wherein the semiconductor pattern includes a plurality of regions spaced apart from each other in the first direction.

10. The semiconductor device of claim 1, wherein a width of the vertical insulating pattern in the second direction is equal to a width of the semiconductor pattern in the second direction.

11. The semiconductor device of claim 1, wherein the vertical insulating pattern has a portion protruding toward the intermediate insulating pattern.

12. The semiconductor device of claim 11, wherein a thickness of the protruding portion of the vertical insulating pattern is the same as a thickness of the intermediate insulating pattern.

13. The semiconductor device of claim 1, further comprising:
a power transfer structure disposed on a lower surface of the substrate insulating layer and electrically connected to the second contact structure.

14. The semiconductor device of claim 1, wherein the second contact structure does not overlap the first contact structure in a vertical direction.

15. A semiconductor device, comprising:
a substrate insulating layer;
a semiconductor pattern extending on the substrate insulating layer in a first direction;
a plurality of channel layers spaced apart from each other in a direction perpendicular to an upper surface of the substrate insulating layer on the substrate insulating layer;
gate structures surrounding the plurality of channel layers on the substrate insulating layer and extending in a second direction perpendicular to the first direction;
source/drain regions disposed on external sides of the gate structures;
a vertical insulating pattern in contact with a bottom surface of the source/drain regions; and
a backside contact structure spaced apart from the vertical insulating pattern in the first direction and electrically connected to at least one of the source/drain regions,
wherein the vertical insulating pattern includes a body portion penetrating the substrate insulating layer and extending from a lower surface of the source/drain regions toward a lower surface of the substrate insulating layer, and a protrusion surrounding at least a portion of a side surface of the body portion.

16. The semiconductor device of claim 15, wherein a thickness of the protrusion is smaller than or equal to a distance between the plurality of channel layers.

17. The semiconductor device of claim 15, further comprising:
an intermediate insulating pattern having the same thickness as a thickness of the protrusion and in contact with a side surface of the protrusion.

18. A semiconductor device, comprising:
a substrate insulating layer;
a fin-type structure extending on the substrate insulating layer in a first direction and including a lower insulating pattern, an intermediate insulating pattern and a semiconductor pattern stacked in order;
a channel structure disposed on the fin-type structure in a direction perpendicular to an upper surface of the substrate insulating layer;
a gate structure intersecting the fin-type structure, surrounding the channel structure, and extending in a second direction orthogonal to the first direction;
first and second source/drain regions disposed on external sides of the gate structure;
a vertical insulating pattern penetrating through the fin-type structure and extending from a lower surface of the first source/drain region toward a lower surface of the substrate insulating layer; and
a backside contact structure spaced apart from the vertical insulating pattern in the first direction and electrically connected to the second source/drain region.

19. The semiconductor device of claim 18, further comprising:
a device isolation layer defining the fin-type structure,
wherein a lowermost end of the vertical insulating pattern is disposed on a level lower than a level of a lower surface of the device isolation layer.

20. The semiconductor device of claim 18, wherein an upper region of the fin-type structure is exposed from an upper surface of a device isolation layer.
